(19) United States
(12) Patent Application Publication
(10) Pub. No.: US 2026/0247627 A1
(43) Pub. Date: Aug. 20, 2026

(54) MEMORY CELL AND METHOD FOR MANUFACTURING THEREOF

(71) Applicant: CHANG GUNG UNIVERSITY, Taoyuan City (TW)

(72) Inventors: Siddheswar Maikap, Taoyuan City (TW); Asim Senapati, Taoyuan City (TW); Abhijit Aich, Taoyuan City (TW); Yi-Pin Chen, Taoyuan City (TW); Zhao-Feng Lou, TAIPEI (TW); Min-Hung Lee, TAIPEI (TW)

(21) Appl. No.: 19/221,929

(22) Filed: May 29, 2025

(30) Foreign Application Priority Data
Feb. 19, 2025 (TW) 114106049

(51) Int. Cl. H10B 53/30

(52) U.S. Cl. CPC H10B 53/30

(57) ABSTRACT

The present application provides a memory cell and a method for manufacturing the same. The memory cell comprises an interfacial capping layer, wherein the interfacial capping layer comprises a first interface layer composed of tungsten nitride and a second interface layer composed of tungsten carbonitride. The first interface layer provides interface tensile tension, which increases the polarization degree of the memory cell. The second interface layer blocks oxygen ions, prevents the first interface layer from being oxidized, and further prevents the top electrode of the memory cell from being oxidized, thereby improving the durability of the memory cell. In addition, the present application further optimizes the annealing process, places the memory cell in the middle of a high-temperature furnace for annealing and heating, and sets a plurality of protection wafers before and after the memory cell to protect the memory cell from stress.

### FIELD OF THE INVENTION

The present application relates to a memory cell and a method for manufacturing thereof, and more particularly, to a memory cell having a nitride-ruthenium compound and a carbonitride-ruthenium compound and a method for manufacturing thereof.

### BACKGROUND OF THE INVENTION

With the development of technologies, nowadays, various types of electronic devices all are popular over the world, including personal computers, notebook computers, calculators, smart phones, and the like.

Wherein, the memory device is an essential device in the various electronic devices. The memory device includes a plurality of memory cells. A memory cell may have a logic "1" indicative of a higher potential and a logic "0" indicative of a lower potential to represent binary bit information, which is maintained (stored) in the storage state of the memory cell until the storage state is changed.

Recently, due to the rapid development of industries such as the Internet of Things(IoT), mobile devices, high-speed computers, and intelligent vehicles, the application requirements of massive computation architectures such as artificial intelligence (AI) and edge computing have been greatly increased. Therefore, the existing high-capacity storage elements such as DRAM and NAND Flash have been unable to follow up with the demand in terms of power consumption and data access speed.

The global memory industry has entered an era where new alternative technologies must be sought. Among the emerging memory technology options, ferroelectric memory is the most promised.

Hafnium dioxide (HfO₂) is a very familiar material in the semiconductor industry. HfO₂ has been widely used as a high-k dielectric material in CMOS and a dielectric material in capacitors of DRAM since semiconductor process in 28nm. Afterward, HfO₂ is also used as a resistive switching material in ReRAM.

In a typical FeRAM memory, the polarization of the ferroelectric capacitor increases with the number of operations (wake-up effect), and then gradually degrades (fatigue effect). The final operation count in the ferroelectric capacitor may be limited by the breakdown of the ferroelectric layer.

The fatigue effect is due to the oxygen vacancies generated at the TiOx at the TiN electrode/HfO₂ ferroelectric layer interface under repeated operations and the resulting in trapping charges. The trapped charges may form new dipoles and result in pinning of the ferroelectric domain walls, and the breakdown of the ferroelectric layer is also related to permanent leakage current paths formed by continuously accumulated number of the oxygen vacancies.

In view of the above problems, the present application provides a memory cell and a method for manufacturing thereof. The memory cell includes an interfacial capping layer disposed on a ferroelectric layer. The interfacial capping layer includes a first interface layer and a second interface layer. The first interface layer provides an interfacial tensile stress increasing the polarization degree of the memory cell. The second interface layer blocks the diffusion of oxygen ions from the ferroelectric layer into the first interface layer, thereby preventing oxidation of the first interface layer and further preventing oxidation of a top electrode, so as to improve the endurance of the memory cell. The present application further optimizes an annealing process for a memory device. After a high-temperature furnace is heated to an annealing temperature, the memory cell is annealed to form the memory device while the memory cell is disposed in a middle place of the high-temperature furnace. An appropriated stress protection is provided for the memory cell while a plurality of protective wafers are respectively disposed in front of and behind the memory cell.

### SUMMARY

An object of the present application is to provide a memory cell and a method for manufacturing thereof. The memory cell is applied for a memory device comprising a plurality of memory cells each including an interfacial capping layer disposed on a ferroelectric layer. The interfacial capping layer includes a first interface layer and a second interface layer. The first interface layer provides an interfacial tensile stress increasing the polarization degree of the memory cell. The second interface layer blocks the diffusion of oxygen ions from the ferroelectric layer into the first interface layer, thereby preventing the first interface layer from oxidation and further preventing a top electrode from oxidation, so as to improve the endurance of the memory cell. The present application further optimizes an annealing process for a memory device. After a high-temperature furnace is heated to an annealing temperature, the memory cell disposed in the middle of the high-temperature furnace is annealed to form the memory device. A plurality of protective wafers are respectively disposed in front of and behind the memory cell to provide an appropriated stress protection for the memory cell.

To achieve the above-mentioned objects, the present application provides a method for manufacturing a memory cell. First, providing a silicon substrate. Next, forming a bottom electrode on the silicon substrate. Then, forming a ferroelectric layer on the bottom electrode. Afterward, forming an interfacial capping layer on the ferroelectric layer while the interfacial capping layer comprises a first interface layer and a second interface layer, wherein an area of the interfacial capping layer is less than or equal to an area of the ferroelectric layer, a material of the first interface layer is selected from WNx, and a material of the second interface layer is selected from WcxNy, further, the first interface layer is disposed on the second interface layer. Thereafter, a top electrode is formed on the interfacial capping layer to form at least one memory cell on the silicon substrate, wherein an area of the top electrode is equal to the area of the interfacial capping layer. Finally, performing an annealing process for the memory cell to form a memory device. In the step of performing an annealing process for the memory cell to form a memory device, the memory cell is placed in a middle place of a high-temperature furnace and subjected to annealing for an annealing time to form the memory device.

In an embodiment of the present application, the high-temperature furnace heats to an annealing temperature less than or equal to 400°C through a plurality of thermocouples.

In an embodiment of the present application, a plurality of protective wafers are further disposed in front of and behind the memory cell to provide appropriate stress protection for the memory cell.

In an embodiment of the present application, in the step of forming a bottom electrode on the silicon substrate and in the step of forming a top electrode on the interfacial capping layer, the step of forming the ferroelectric layer on the bottom electrode is performed by forming the ferroelectric layer by using an Atomic Layer Deposition (ALD) process, and the step of forming the interfacial capping layer on the ferroelectric layer is performed by forming the interfacial capping layer by the ALD process. The first interface layer (WNx) provides interface tensile tension to increase the polarization degree of the memory cell; the second interface layer (WCxNy) blocks the oxygen ions of the ferroelectric layer from diffusing into the first interface layer, preventing the first interface layer from oxidizing, and further preventing the top electrode from oxidizing, thereby improving the durability of the memory cell.

To achieve the above-mentioned objects, the present application further provides a memory cell, applied for a memory device, comprising a plurality of memory cells and a silicon substrate. Each of the memory cells comprises a bottom electrode, a ferroelectric layer, an interfacial capping layer and a top electrode. The bottom electrode is disposed on the silicon substrate, and the ferroelectric layer is disposed on the bottom electrode. The interfacial capping layer is disposed on the ferroelectric layer and comprises a first interface layer and a second interface layer, and the top electrode is disposed on the interfacial capping layer, wherein an area of the interfacial capping layer is less than or equal to an area of the ferroelectric layer, a material of the first interface layer is selected from WNx, and a material of the second interface layer is selected from WcxNy, further, the first interface layer is disposed on the second interface layer, and an area of the top electrode is equal to the area of the interfacial capping layer. The first interface layer (WNx) provides interface tensile stress, so that the polarization degree of the memory cell is increased; the second interface layer (WCxNy) blocks the diffusion of oxygen ions of the ferroelectric layer to the first interface layer, prevents the first interface layer from being oxidized, and further prevents the top electrode from being oxidized, thereby improving the endurance of the memory cell.

In another embodiment of the present application, wherein a material of the ferroelectric layer is selected from the group consisting of HfZrOx, HfSiOx, HfOx, HfYOx, HfGdOx, HfSrOx, SrTiOx, SrCaTiO₃, Ag(Nb1-xTax)O₃, BaSrTiO₃, BaTiO₃, ZrOx, and HfAlOx, and a material of the bottom electrode and the top electrode is selected from the group consisting of Zr, Hf, TiN, Ti, Ta, TaN, TaSi, TaCN, TiAlN, Zn, Ni, NiSi, Ru, C, Si, SiNx, Ge, Pt, Al, AlN, Y, Gd, Sr, W, WSi, WN, Ga, and GaN.

In another embodiment of the present application, wherein the thermal expansion coefficient of the interfacial capping layer is lower than that of the top electrode to avoid deformation of the memory cell.

In another embodiment of the present application, wherein the interfacial capping layer is formed on the ferroelectric layer through an Atomic Layer Deposition (ALD) process, and the first interface layer is formed on the second interface layer through the ALD process, and the second interface layer is formed on the ferroelectric layer through the ALD process, the first interface layer provides an interfacial tensile stress between the top electrode and the second interface layer, the first interface layer provides an interfacial tensile stress between the top electrode and the second interface layer to increase the polarization degree of the memory cell.

In another embodiment of the present application, wherein the second interface layer blocks oxygen ions generated by the ferroelectric layer to prevent oxidation of the first interface layer, and further prevent oxidation of the top electrode, thereby improving the endurance of the memory cell.

### BRIEF DESCRIPTION OF THE DRAWINGS

FIG. 1: which is a schematic diagram of a memory cell according to an embodiment of the present application;

FIG. 2: which is a schematic diagram of a transmission electron microscope image according to an embodiment of the present application;

FIG. 3: which is another schematic diagram of a memory cell according to an embodiment of the present application;

FIG. 4: which is a flow chart of a method for manufacturing a memory cell according to an embodiment of the present application;

FIG. 5: which is a schematic diagram of an annealing process environment according to an embodiment of the present application;

FIGS. 6A and 6B: which are a schematic diagram of voltage versus remanent polarization (2Pr value) and a schematic diagram of material versus remanent polarization (2Pr value) according to an embodiment of the present application;

FIG. 7: which is a schematic diagram of voltage versus remanent polarization (2Pr value) of a memory cell according to an embodiment of the present application;

FIG. 8: which is a schematic diagram of remanent polarization versus pulse width of a memory cell after wake-up according to an embodiment of the present application; and

FIG. 9: which is a schematic diagram of endurance test results of a memory cell according to an embodiment according to the present application.

### DETAILED DESCRIPTION

To enable those in the art who are skilled in the art to better understand and appreciate the features and advantages of the present application, the preferred embodiments and the accompanying detailed description are given as follows:

Throughout the description and claims of this specification, certain terms are used for the sake of convenience, but without limiting the scope of the application. The terms "comprise", "include" and "have", when used in this specification and in the following claims, are intended to specify the presence of stated features, integers, steps, operations, processes, acts, elements, or components, but they do not preclude the presence or addition of one or more other features, integers, steps, operations, processes, acts, elements, components, or groups thereof. In addition, the word "exemplary" is used herein to mean "serving as an example, instance, or illustration." Any implementation or embodiment described herein as "exemplary" is not necessarily to be construed as preferred or advantageous over other implementations or embodiments. In addition, the term "plurality" is used herein to mean "two or more." The term "another," when used herein, means "at least one." The term "substantially" when used herein means "to a great extent or degree." The term "comprising" means "including, but not limited to." The term "coupled" means to be directly or indirectly connected physically or logically, or to be directly or indirectly in physical or logical contact. The term "substantially" means "to a great extent or degree." The term "coupled" means to be directly or indirectly connected physically or logically, or to be directly or indirectly in physical or logical contact.

In light of the polarization of the conventional ferroelectric memory increasing with the number of operations (wake-up effect), and then gradually degrades (fatigue effect). Oxygen vacancies generated at the interface between the bottom electrode and the ferroelectric layer under repeated operations cause charge trapping. The top electrode and the first interface layer are oxidized due to the diffusion of oxygen ions from the ferroelectric layer, thereby reducing the durability of the memory cell.

To overcome the above issues, the present application provides a memory cell and a method of manufacturing thereof. The memory cell is applied for a memory device, and the memory device includes a plurality of memory cells each including an interfacial capping layer disposed on a ferroelectric layer. The interfacial capping layer includes a first interface layer and a second interface layer. The first interface layer provides an interfacial tensile stress, which increases the polarization degree of the memory cell. The second interface layer blocks oxygen ions to prevent oxidation of the first interface layer and further prevent oxidation of a top electrode. Furthermore, the annealing process of a memory device is optimized. After a high-temperature furnace is heated to an annealing temperature, the memory cell in the middle is annealed, and a plurality of protective wafers are disposed in front of and behind the memory cell to protect the memory cell with appropriate stress.

In the following description, illustrative embodiments of the present application are described with reference to the accompanying drawings. However, the inventive concept may be embodied in many different forms and should not be construed as being limited to the exemplary embodiments set forth herein.

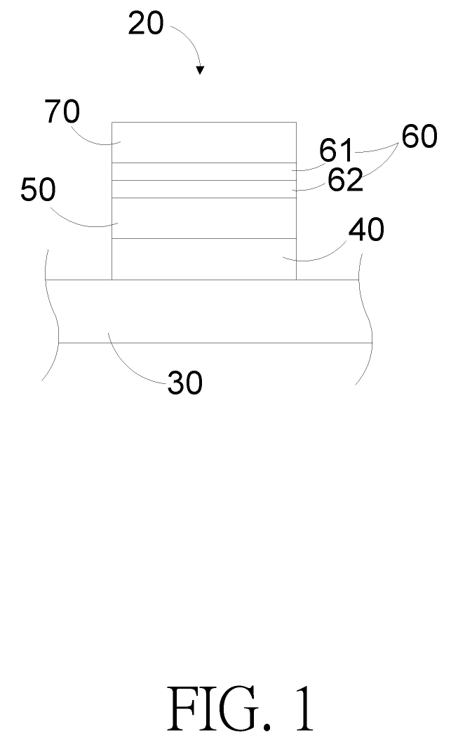

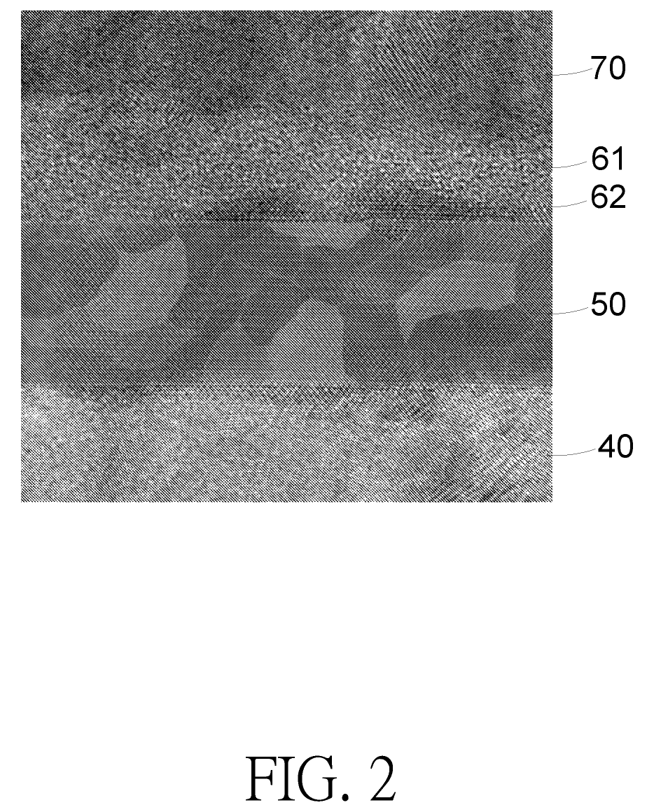

Firstly, refer to FIG. 1 to FIG. 3. A memory cell of the present application is applied to a memory device 10, the memory device 10 includes a plurality of memory cells 20 and a silicon substrate 30, each of the memory cells 20 includes a bottom electrode 40 disposed on the silicon substrate 30, a ferroelectric layer 50 disposed on the bottom electrode 40, an interfacial capping layer (ICL) 60 disposed on the ferroelectric layer 50, and a top electrode 70 disposed on the interfacial capping layer 60, wherein the ICL 60 includes a first interface layer 61 selected from a group consisting of WNx and a second interface layer 62 selected from a group consisting of WCNy, the first interface layer 61 is disposed on the second interface layer 62.

Wherein the ICL 60 is formed on the ferroelectric layer 50 by an Atomic Layer Deposition (ALD) process, and the first interface layer 61 is formed on the second interface layer 62 by the ALD process, the second interface layer 62 is formed on the ferroelectric layer 50 by the ALD process, the first interface layer 61 provides an interfacial tensile stress between the top electrode 70 and the second interface layer 62, the first interface layer 61 is disposed between the second interface layer 62 and the top electrode 70 to provide an interfacial tensile stress between the second interface layer 62 and the top electrode 70, so that the polarization degree of the memory cell 20 is increased. The second interface layer 62 is disposed between the ferroelectric layer 50 and the first interface layer 61 to block the diffusion of oxygen ions generated by the ferroelectric layer 50 to the first interface layer 61, prevent the oxidation of the first interface layer 61, and further prevent the oxidation of the top electrode 70, thereby improving the endurance of the memory cell 20.

Wherein, in this embodiment, the thickness of the bottom electrode 40 is 40nm, the thickness of the ferroelectric layer is 10nm, the thickness of the first interface layer is 2nm, the thickness of the second interface layer is 2nm, and the thickness of the top electrode is >30nm.

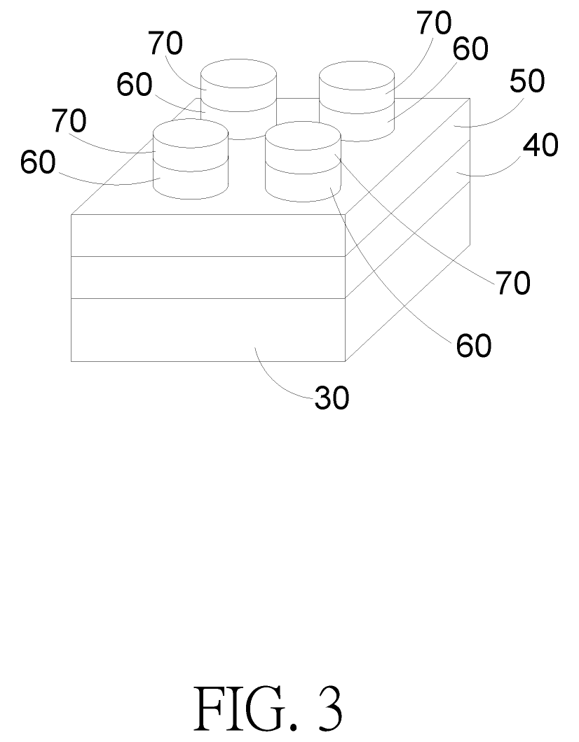

Referring to FIG. 1 and FIG. 3, the area of the interfacial capping layer 60 is less than or equal to the area of the ferroelectric layer 50, and the area of the top electrode 70 is equal to the area of the interfacial capping layer 60, wherein the material of the ferroelectric layer 50 is selected from the group consisting of HfZrOx, HfSiOx, HfOx, HfYOx, HfGdOx, HfSrOx, SrTiOx, SrCaTiO₃, Ag(Nb1-xTax)O₃, BaSrTiO₃, BaTiO₃, ZrOx, and HfAlOx.

The material of the bottom electrode 40 and the top electrode 70 is selected from the group consisting of Zr, Hf, TiN, Ti, Ta, TaN, TaSi, TaCN, TiAlN, Zn, Ni, NiSi, Ru, C, Si, SiNx, Ge, Pt, Al, AIN, Y, Gd, Sr, W, WSi, WN, Ga, and GaN.

Wherein the thermal expansion coefficient of the interfacial capping layer 60 is lower than that of the top electrode 70.

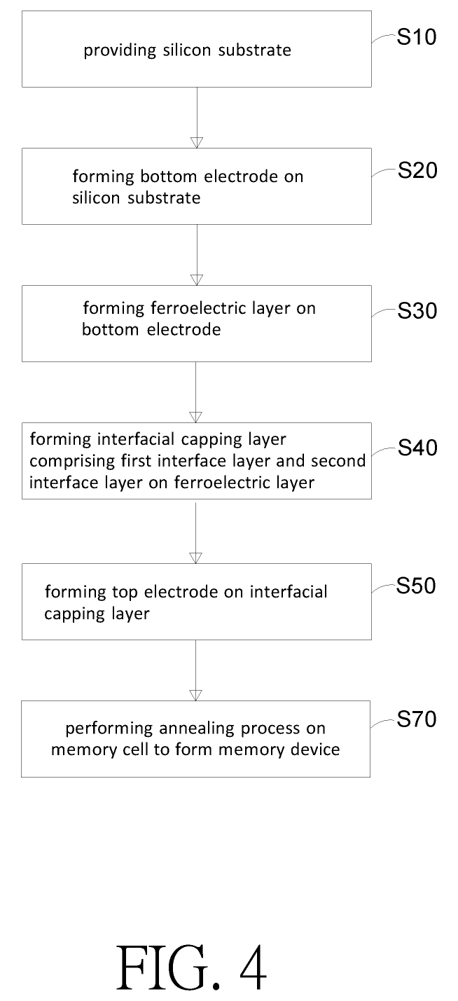

Referring to FIG. 4, which is a flow chart of a method for manufacturing a memory cell according to an embodiment of the present application, the steps of the method for manufacturing a memory cell according to an embodiment of the present application are as follows:

Step S10: providing a silicon substrate;

Step S20: forming a bottom electrode on the silicon substrate;

Step S30: forming a ferroelectric layer on the bottom electrode;

Step S40: forming an interfacial capping layer comprising a first interface layer and a second interface layer on the ferroelectric layer;

Step S50: forming a top electrode on the interfacial capping layer; and

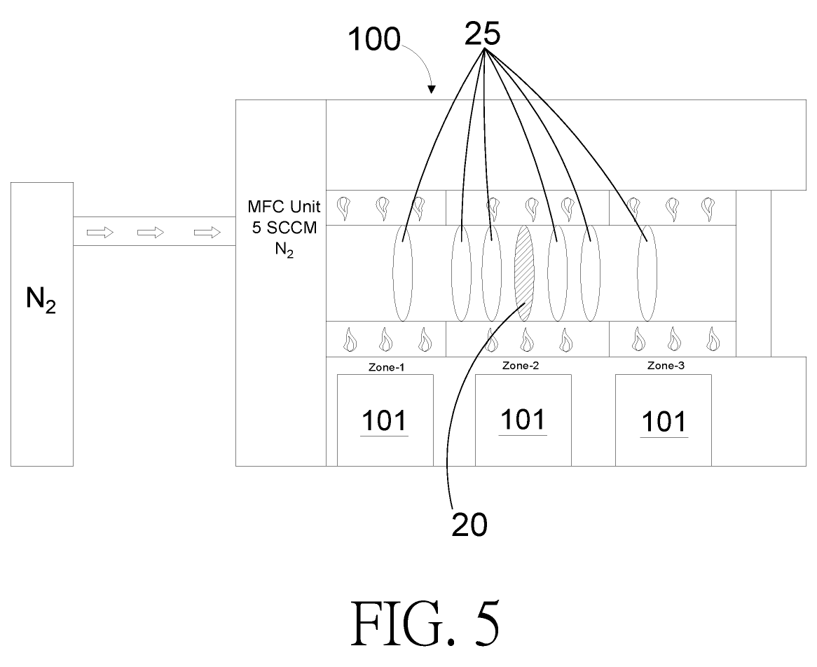

Step S70: performing an annealing process on the memory cell to form a memory device.

Wherein, in step S10, a silicon substrate 30 is provided in the process of the memory cell 20 of the present application, and the material of the silicon substrate 30 is selected from a group consisting of single crystal silicon, polysilicon, silicon nitride (Si₃N₄) or silicon carbide (SiC).

Wherein, in step S20, a bottom electrode 40 is formed on the silicon substrate 30 by using a radio frequency sputtering process, and the material of the bottom electrode 40 is selected from a group consisting of zirconium (Zr), hafnium (Hf), titanium nitride (TiN), titanium (Ti), tantalum (Ta), tantalum nitride (TaN), tantalum silicide (TaSi), tantalum carbonitride (TaCN), titanium aluminum nitride (TiAlN), zinc (Zn), nickel (Ni), nickel silicide (NiSi), ruthenium (Ru), carbon (C), silicon (Si), silicon nitride (Si₃N₄), germanium (Ge), platinum (Pt), aluminum (Al), aluminum nitride (AIN), yttrium (Y), gadolinium (Gd), strontium (Sr), tungsten (W), tungsten silicide (WSi), tungsten nitride (WN), gallium (Ga), and gallium nitride (GaN).

Wherein, in step S30, the ALD process is used to form a ferroelectric layer 50 on the bottom electrode 40, and the material of the ferroelectric layer 50 is selected from a group consisting of hafnium zirconium oxide (HfZrOx), hafnium silicon oxide (HfSiOx), hafnium oxide (HfOx), hafnium yttrium oxide (HfYOx), hafnium gadolinium oxide (HfGdOx), hafnium strontium oxide (HfSrOx), strontium titanium oxide (SrTiOx), strontium calcium titanium oxide (SrCaTiO₃), Ag(Nb1-xTax)O₃, barium strontium titanium oxide (BaSrTiO₃), barium titanium oxide (BaTiO₃), zirconium oxide (ZrOx), or hafnium aluminum oxide (HfAlOx).

Wherein, in step S40, the ALD process is used to form the interfacial capping layer 60 on the ferroelectric layer 50, so as to sequentially form the first interface layer 61 and the second interface layer 62 on the ferroelectric layer 50, and the area of the interfacial capping layer 60 is less than or equal to the area of the ferroelectric layer 50.

Wherein, in step S50, the RF sputtering process is used to form the top electrode 70 on the interfacial capping layer 60, and the material of the top electrode 70 is selected from the group consisting of zirconium (Zr), hafnium (Hf), titanium nitride (TiN), titanium (Ti), tantalum (Ta), tantalum nitride (TaN), tantalum silicide (TaSi), tantalum carbonitride (TaCN), titanium aluminum nitride (TiAlN), zinc (Zn), nickel (Ni), nickel silicide (NiSi), ruthenium (Ru), carbon (C), silicon (Si), silicon nitride (SiNx), germanium (Ge), platinum (Pt), aluminum (Al), aluminum nitride (AIN), yttrium (Y), gadolinium (Gd), strontium (Sr), tungsten (W), tungsten silicide (WSi), tungsten nitride (WN), gallium (Ga), and gallium nitride (GaN). Wherein, the area of the top electrode 70 is equal to the area of the interfacial capping layer 50, the thermal expansion coefficient of the interfacial capping layer 60 is lower than that of the top electrode 70, and the first interface layer 61 is located between the second interface layer 62 and the top electrode 70, so as to provide interface tensile stress, thereby increasing the polarization degree of the memory cell 20. Thereby, the steps S20-S50 are equivalent to a step of forming at least one memory cell 20 on the silicon substrate 30.

Wherein, in step S70, referring further to FIG. 5, which is a schematic diagram of an annealing process environment of a method for manufacturing a memory cell of the present application, a wafer with the memory cells 20 disposed thereon is placed in a high temperature furnace 100 for annealing for an annealing time to form a memory device 10, the high temperature furnace 100 is heated to an annealing temperature by a plurality of thermocouples 101, the annealing time is 0.5 hours to 1.5 hours, the annealing temperature is less than or equal to 400°C, the plurality of thermocouples 101 control the annealing temperature to a temperature error of ±2°C, for example, in the high temperature furnace 100, after being heated to the annealing temperature by the plurality of thermocouples 101 and filled with nitrogen N₂ at 5000 standard milliliter per minute (5 SLM), a wafer with the memory cells 20 disposed thereon is placed in the high temperature furnace 100 for 2 minutes, annealed for 1 hour, and then taken out of the high temperature furnace 100 for 2 minutes, further, in the high temperature furnace 100, a plurality of protective wafers 25, for example, 3 protective wafers 25, are disposed before and after the wafer with the memory cells 20 disposed thereon to provide thermal stress protection and protect the memory cells 20, thereby being applicable to a back end of line (BEOL) process or a batch process.

Referring back to FIG. 5, which is a schematic diagram of an annealing process environment according to an embodiment of the present application. In step S70, nitrogen (N₂) is flowed into the high temperature furnace 100 at 5000 standard milliliter per minute by an MFC flowmeter to make the high temperature furnace 100 a nitrogen atmosphere environment, the high temperature furnace 100 is heated to <400°C by the plurality of thermocouples 101, the inside of the high temperature furnace 100 is roughly divided into three regions, front, middle, and back, corresponding to the heating regions of the plurality of thermocouples 101, the wafer with the memory cells 20 disposed thereon is placed in the middle region of the high temperature furnace 100, the plurality of protective wafers 25 are disposed before and after the wafer with the memory cells 20 disposed thereon, that is, the plurality of protective wafers 25 are disposed in the front and back regions of the high temperature furnace 100 to provide thermal stress protection and protect the wafer with the memory cells 20 disposed thereon.

Through the above annealing process, the interfacial capping layer 60 and the ferroelectric layer 50 of the memory cell 20 are recrystallized, thereby the existing Contant On-Time (COT) of the memory cell 20 of the present application may be further reduced, and the response time of the memory cell 20 is improved.

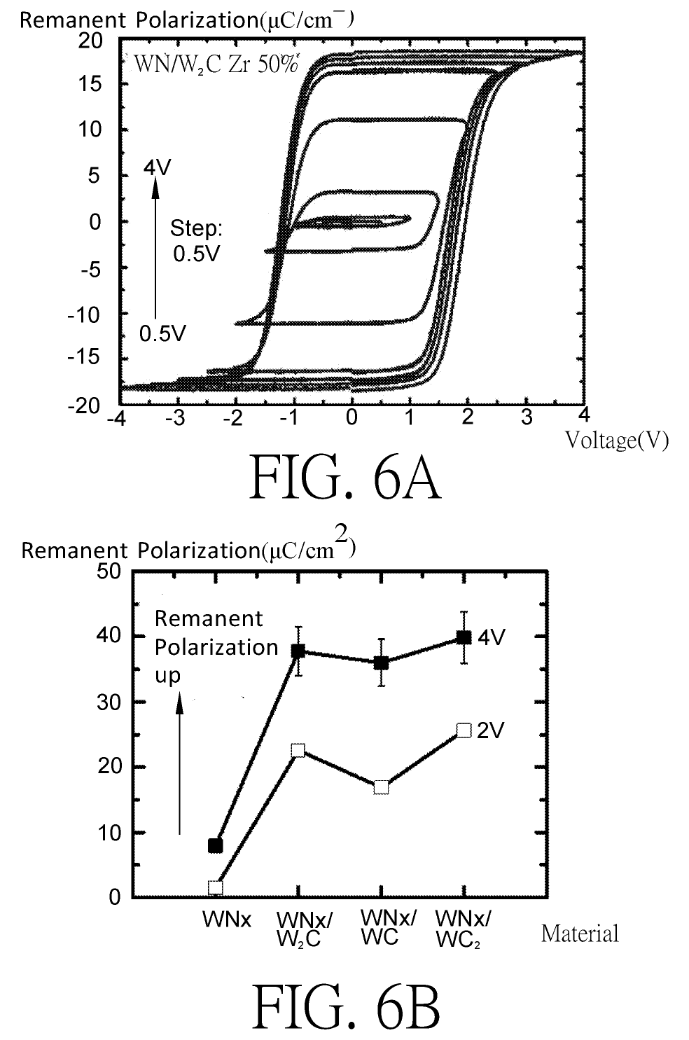

Referring to FIGS. 6A and 6B, which are a schematic diagram of voltage versus remanent polarization (2Pr value) and a schematic diagram of material versus remanent polarization (2Pr value) according to an embodiment of the present application. Because the second interface layer 62 of the interfacial capping layer 60 blocks oxygen ions, resulting in a reduction in the generation of oxides, thereby increasing the 2Pr value. As shown in FIG. 6A, when the material of the second interface layer 62 is a 1:1 molar ratio of WN and W2C, the working voltage is gradually increased from ±0.5V to ±4.0V, with each stage increasing by 0.5V. As shown in FIG. 6B, the change in remanent polarization value (2Pr value) of pure WN and carbonitride compounds, wherein the carbonitride compound refers to a mixture of a tungsten carbide compound and a tungsten nitride compound (WNx), such as a tungsten nitride compound/tungsten dicarbide (WNx/W2C), a tungsten nitride compound/tungsten carbide (WNx/WC), and a tungsten nitride compound/acetylide (WNx/WC2). The solid square indicates a working voltage of 4V, and the open square indicates a working voltage of 2V. It may be seen that the remanent polarization value of the carbonitride compound is better than that of the pure tungsten nitride compound. In this embodiment, the thickness of the ferroelectric layer is 10nm, and the thickness of the interfacial capping layer is 4nm.

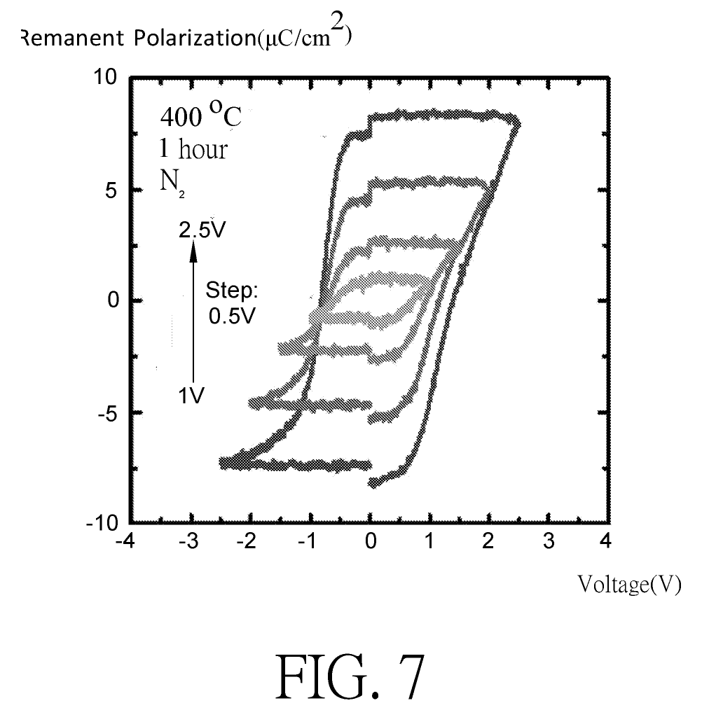

Referring to FIG. 7, which is a schematic diagram of voltage versus remanent polarization (2Pr value) of a memory cell according to an embodiment of the present application. As shown in the figure, this embodiment according to the present application, which sets the interfacial capping layer of the present application on a ferroelectric layer with a thickness of 5nm, has a better change in polarity, especially at a working voltage of ±1V, and may be applied to a cache memory. In this embodiment, the operating environment is a nitrogen (N₂) environment, the working voltage is ±1V to ±2.5V, with each stage voltage being 0.5V, the working temperature is 400 ^{o}C, and the working time is 1 hour.

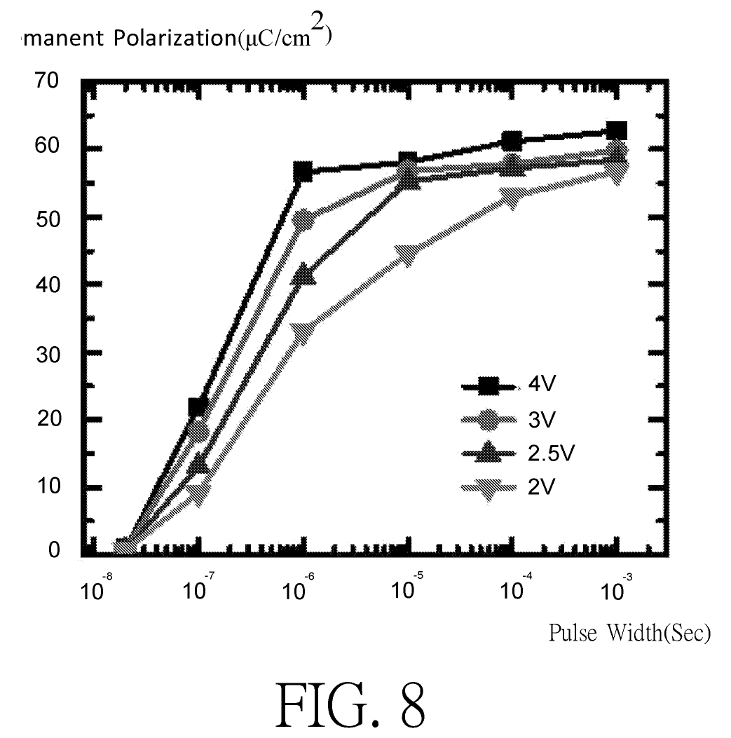

Referring to FIG. 8, which is a schematic diagram of remanent polarization versus pulse width of a memory cell after wake-up according to an embodiment of the present application. After wake-up, it may be seen that the memory cell of the present application has a good polarity after wake-up. For the residual polarization value of the pulse width between 10⁸ second and 10³ second at the operating voltage of 2V to 4V, the wider the pulse width, i.e. the longer the second, the higher the residual polarization value.

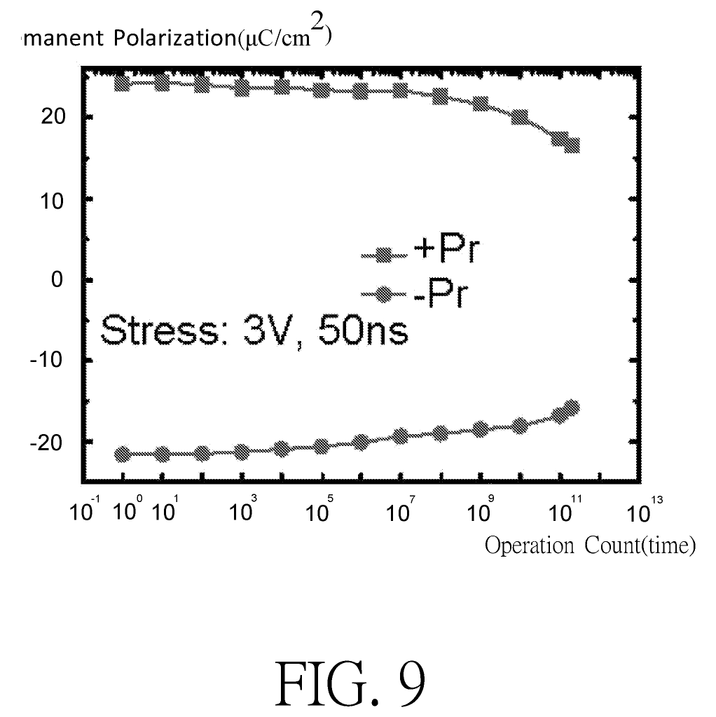

Referring to FIG. 9, which is a schematic diagram of endurance test results of a memory cell according to an embodiment according to the present application, as shown in the figure, the memory cell according to the present application has a good endurance. For the operating voltage of 3V and the access time of 50 nanoseconds (ns), the operating times of the on state (+Pr) and the off state (-Pr) may be as high as 1011 times or more.

To sum up, the present application is a memory cell and a method for manufacturing thereof. The memory cell applied for a memory device comprising a plurality of memory cells, and each of the memory cells comprises a top electrode, a ferroelectric layer, an interfacial capping layer and a bottom electrode, which are sequentially disposed on a silicon substrate, for application to a memory device. The interfacial capping layer is disposed on the ferroelectric layer. The interfacial capping layer comprises a first interface layer and a second interface layer. The first interface layer provides an interface tensile stress, which increases the polarization degree of the memory cell. The second interface layer is disposed between the ferroelectric layer and the first interface layer, for blocking the diffusion of the oxygen ions generated from the ferroelectric layer to the first interface layer, prevents the oxidation of the first interface layer, and further prevents the oxidation of the top electrode, thereby improving the endurance of the memory cell. Furthermore, an annealing process is provided for the memory device. After heating a high-temperature furnace to an annealing temperature, annealing is performed on the memory cell in the middle. Furthermore, a plurality of protective wafers are disposed in front of and behind the memory cells in the high-temperature furnace, so as to provide a thermal stress protection for the memory cell.

Therefore, the present application indeed possesses novelty, progressiveness, and industrial applicability, undoubtedly meeting the requirements for a patent application under the national patent law. Accordingly, a patent application has been legally filed, earnestly praying for the patent application grant to be issued soon.

However, the above description is merely an embodiment of the present application and is not intended to limit the scope of the present application. Therefore, all equivalent modifications and variations according to the structure, and the features described in the scope of the patent application should be included within the scope of this patent application.

What is claimed is:

1. A method for manufacturing a memory cell, comprising:
providing a silicon substrate;
forming at least one memory cell on the silicon substrate, comprising:
forming a bottom electrode on the silicon substrate;
forming a ferroelectric layer on the bottom electrode;
forming an interfacial capping layer on the ferroelectric layer, the interfacial capping layer having an area less than or equal to an area of the ferroelectric layer, the interfacial capping layer comprising a first interface layer and a second interface layer, the first interface layer being selected from a group consisting of a nitride rhenium compound, the second interface layer being selected from a group consisting of a carbonitride rhenium compound, the first interface layer being formed on the second interface layer; and
forming a top electrode on the interfacial capping layer, the top electrode having an area equal to an area of the interfacial capping layer; and
performing an annealing process on the memory cell to form a memory device.

2. The method of claim 1, wherein in the step of performing an annealing process on the memory cell to form a memory device, the high temperature furnace is heated to an annealing temperature by a plurality of thermocouples, the annealing temperature being less than or equal to 400°C, which is used to drive the recrystallization of the interfacial capping layer and the ferroelectric layer.

3. The method of claim 1, wherein in the step of performing an annealing process on the memory cell to form a memory device, a plurality of protective wafers are placed before and after the memory cell to provide a thermal stress protection to a wafer on which the memory cell is located.

4. The method of claim 1, wherein in the step of forming a bottom electrode on the silicon substrate and the step of forming a top electrode on the interfacial capping layer, a radio frequency sputtering process is used to perform the step of forming the bottom electrode on the silicon substrate and the step of forming the top electrode on the interfacial capping layer.

5. The method of claim 1, wherein in the step of forming a ferroelectric layer on the bottom electrode and the step of forming an interfacial capping layer on the ferroelectric layer, an atomic layer deposition (ALD) process is used to form the ferroelectric layer to perform the step of forming the ferroelectric layer on the bottom electrode, and to form the interfacial capping layer by the atomic layer deposition process to perform the step of forming the interfacial capping layer on the ferroelectric layer.

6. A memory cell, applied to a memory device, the memory device comprising a plurality of memory cells and a silicon substrate, each of the memory cells comprising:
a bottom electrode, disposed on the silicon substrate;
a ferroelectric layer, disposed on the bottom electrode;
an interfacial capping layer, disposed on the ferroelectric layer, an area of the interfacial capping layer being less than or equal to an area of the ferroelectric layer, the interfacial capping layer comprising a first interface layer and a second interface layer, a material of the first interface layer being selected from a nitrogen-rhenium compound, a material of the second interface layer being selected from a carbon-nitrogen-rhenium compound, wherein the first interface layer is disposed on the second interface layer; and
a top electrode, disposed on the interfacial capping layer, an area of the top electrode being equal to an area of the interfacial capping layer.

7. The memory cell of claim 6, wherein a material of the ferroelectric layer is selected from a group consisting of Hafnium Zirconium Oxide (HfZrOx), Hafnium Silicon Oxide (HfSiOx), Hafnium Oxide (HfOx), Hafnium Yttrium Oxide (HfYOx), Hafnium Gadolinium Oxide (HfGdOx), Hafnium Strontium Oxide (HfSrOx), Strontium Titanium Oxide (SrTiOx), Calcium Strontium Titanate (SrCaTiO3), Ag(Nbi_xTax)O3, Barium Strontium Titanate (BaSrTiO3), Barium Titanate (BaTiO3), Zirconium Oxide (ZrOx), and Hafnium Aluminum Oxide (HfAlOx), and a material of the bottom electrode and the top electrode is selected from a group consisting of Zirconium (Zr), Hafnium (Hf), Titanium Nitride (TiN), Titanium (Ti), Tantalum (Ta), Tantalum Nitride (TaN), Tantalum Silicide (TaSi), Tantalum Carbon Nitride (TaCN), Titanium Aluminum Nitride (TiAlN), Zinc (Zn), Nickel (Ni), Nickel Silicide (NiSi), Ruthenium (Ru), Carbon (C), Silicon (Si), Silicon Nitride (SiNx), Germanium (Ge), Platinum (Pt), Aluminum (Al), Aluminum Nitride (AIN), Yttrium (Y), Gadolinium (Gd), Strontium (Sr), Tungsten (W), Tungsten Silicide (WSi), Tungsten Nitride (WN), Gallium (Ga), and Gallium Nitride (GaN).

8. The memory cell of claim 1, wherein a coefficient of thermal expansion of the interfacial capping layer is lower than the top electrode.

9. The memory cell of claim 8, wherein the interfacial capping layer is formed on the ferroelectric layer by an atomic layer deposition process, and the first interfacial layer is formed on the second interfacial layer by the atomic layer deposition, process the second interfacial layer is formed on the ferroelectric layer by the atomic layer deposition process, the first interfacial layer provides an interfacial tensile stress between the top electrode and the second interfacial layer.

10. The memory cell of claim 1, wherein the second interfacial layer blocks oxygen ions generated by the ferroelectric layer.
